(19) United States
(12) Patent Application Publication
(10) Pub. No.: US 2007/0187808 A1
(43) Pub. Date: Aug. 16, 2007

(54) Customizable power and ground pins

(75) Inventors: Stan J. Mihelcic, Pleasanton, CA (US); Adam Levinthal, Redwood City, CA (US); Laurence H. Cooke, Los Gatos, CA (US)

Correspondence Address: CONNOLLY BOVE LODGE & HUTZ LLP, 1875 EYE STREET, N.W., SUITE 1100, WASHINGTON, DC, 20036, US

(73) Assignee: eASIC Corporation, Santa Clara, CA (US)

(21) Appl. No.: 11/354,957

(22) Filed: Feb. 16, 2006

(51) Int. Cl. H01L 23/02

(52) U.S. Cl. 257/678

(57) ABSTRACT

A configurable logic array composed of: a multiplicity of logic cells, each containing look-up tables, a multiplicity of customizable I/O cells, each containing a multiplicity of pads; and a customizable via connection layer for customizing the cells and interconnect between them, may be constructed to include the option of customizing the I/O cells to act as power or ground pins. Assigning custom power and ground pins may depend on the types of I/O cells and package bonding options.

### FIELD OF THE INVENTION

The present invention relates to integrated circuit devices as well as to methods for personalizing the power and ground connections to such devices.

### BACKGROUND OF THE INVENTION

The following U.S. patent applications and granted patents are believed to represent the current state of the art: U.S. Pat. Nos. 5,898,225, 6,015,723, 6,331,733, 6,245,634, 6,819,229, 6,194,912 and application Ser. No. 10/899,020.

The above patents describe semiconductor devices, which contain logic cells that further contain look up tables and interconnects, which may be patterned by a single via mask. The advantages of such application-specific integrated circuits (ASICs) have been clearly defined in the prior art, but are limited to logical functions. Today, most semiconductor devices also comprise numerous high-speed output devices. These devices switch large amounts of current, which causes their power and ground rings to bounce. In addition, the increasingly smaller chips that can hold increasingly large amounts of digital logic have necessitated the placement of multiple staggered rows of bonding pads on the chips to provide sufficient I/O. This, in turn, requires multiple rows of pads on the corresponding packages. All of this results in longer wire bonds between the chip and the package, which have more inductance, further aggravating the already problematic power and ground noise caused by the faster switching speeds of the high speed output devices.

As a result, in custom ASICs it is now common to require additional power and ground pins be distributed within groups of such output devices to minimize the electrical bounce, particularly if many such output devices switch at the same time. This reduces the power and ground noise, ensuring the adjacent quiescent outputs will not erroneously switch. Usually the chip designers must either limit the number of such output devices that switch at the same time or add additional power and ground pins.

Field-programmable gate arrays (FPGAs), on the other hand, have a fixed arrangement of such power and ground pins, and therefore must limit the chip designer's use of adjacent simultaneously switching outputs, and cannot provide the alternative of adding additional power and ground pins.

While Choi describes a way to selectively bond power and ground pads to a package substrate, in U.S. Pat. Nos. 6,015,723 granted Jan. 18, 2000, and 5,898,225 granted Apr. 27, 1999, he does not describe a technique for customizing such pads or a method for selecting which I/O sites to customize.

### SUMMARY OF THE INVENTION

The present invention seeks to provide an improved integrated circuit, which, in addition to the teachings of the prior art, has I/O pins which are customizable into power and ground connections to satisfy the simultaneous switching requirements of the rest of the customized I/O pins.

Embodiments of the current invention, in addition to providing a set of single via customizable components, also provide single via customizable power and ground connections within the I/O cells. Depending on the packaging options, the bonded but unused I/O sites may be customized as power or ground pins, or unused I/O sites that are customized as power or ground pins may be custom bonded either to power/ground planes in the package or directly to package pins, as needed to minimize the noise produced by the simultaneously switching output buffers.

There is thus provided in accordance with a preferred embodiment of the present invention a semiconductor device comprising: a multiplicity of logic cells; a multiplicity of customizable I/O cells; and metal and via connection layers overlying the multiplicity of logic and I/O cells for providing at least one permanent customized interconnect between various inputs and outputs, where at least one of the customizable I/O cells connects at least one of the I/O cell's multiplicity of pads to the power or the ground for the customizable I/O cells, and the connection of the I/O cell's pad is customized by at least one via on a single via layer.

It is also provided that a package comprising a multiplicity of package pads connecting either to an internal power plane, or to a pin of the package; and such a semiconductor device as described above that has at least one of the I/O cell's multiplicity of pads that is connected to either the power or the ground connected to one of either type of package pads.

There is additionally provided in a preferred embodiment of the present invention a method for defining the placement of power and ground connections for a semiconductor device within a package, including the steps of:

a) creating an electrical model of each output type,

b) running simultaneous switching experiments on said models,

c) generating a set of noise and delay coefficients for said each output type, and

d) using said coefficients to modify the placement of said I/O cells to meet noise and timing constraints, where modifying the placement of the I/O cells includes the insertion of at least one I/O cell customized as a power or ground connection.

### BRIEF DESCRIPTION OF THE DRAWINGS

The present invention will be understood and appreciated more fully from the following detailed description, taken in conjunction with the drawings in which:

FIG. 1 is a simplified illustration of a semiconductor device containing a multiplicity of logic cells, RAM blocks, ROM blocks, I/O cells, and a clock distribution structure;

FIG. 2 is a simplified illustration of a customizable I/O cell;

FIG. 3 is an illustration of the physical power and ground connections within a customizable I/O cell;

FIG. 4 is a top illustration of a semiconductor device with I/O cells in a multi-tiered package;

FIG. 5 is a side view of the illustration in FIG. 4;

FIG. 6 is a side view of a package with a second bonding pattern;

FIG. 7 is a side view of a package with a third bonding pattern;

FIG. 8 is a diagram depicting power and ground bounce on a quiescent I/O, and;

FIG. 9 is a flowchart for generating noise and delay coefficients and their use in assigning pins.

### DETAILED DESCRIPTION OF VARIOUS EMBODIMENTS

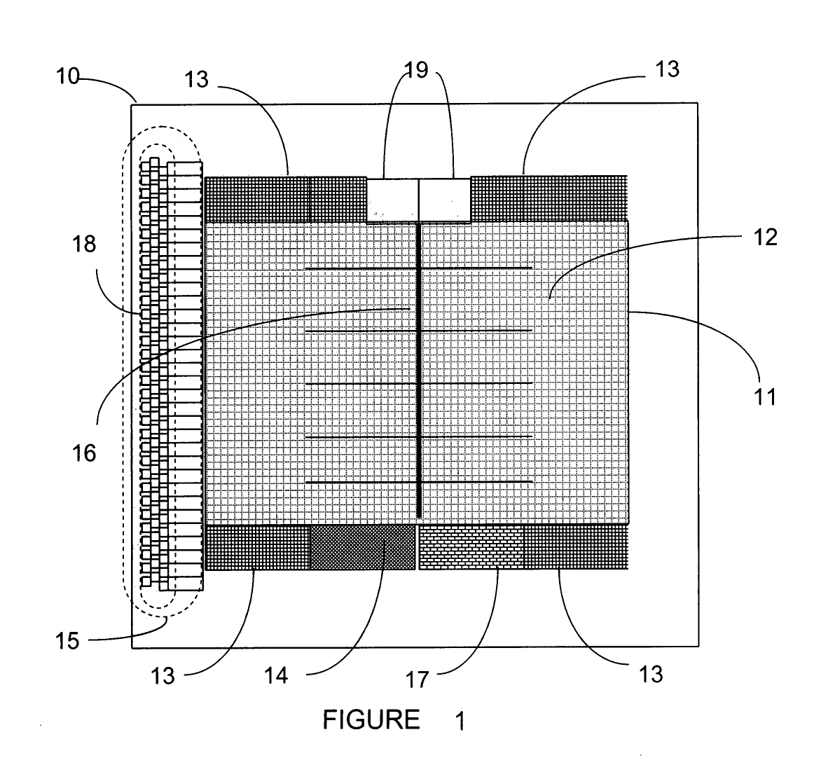

Reference is now made to FIG. 1, which is a simplified illustration of a personalizable and programmable integrated circuit device 10 constructed and operative in accordance with a preferred embodiment of the present invention. The device contains four groups of customizable I/O buffers 15, each with three tiers of I/O pads 18.

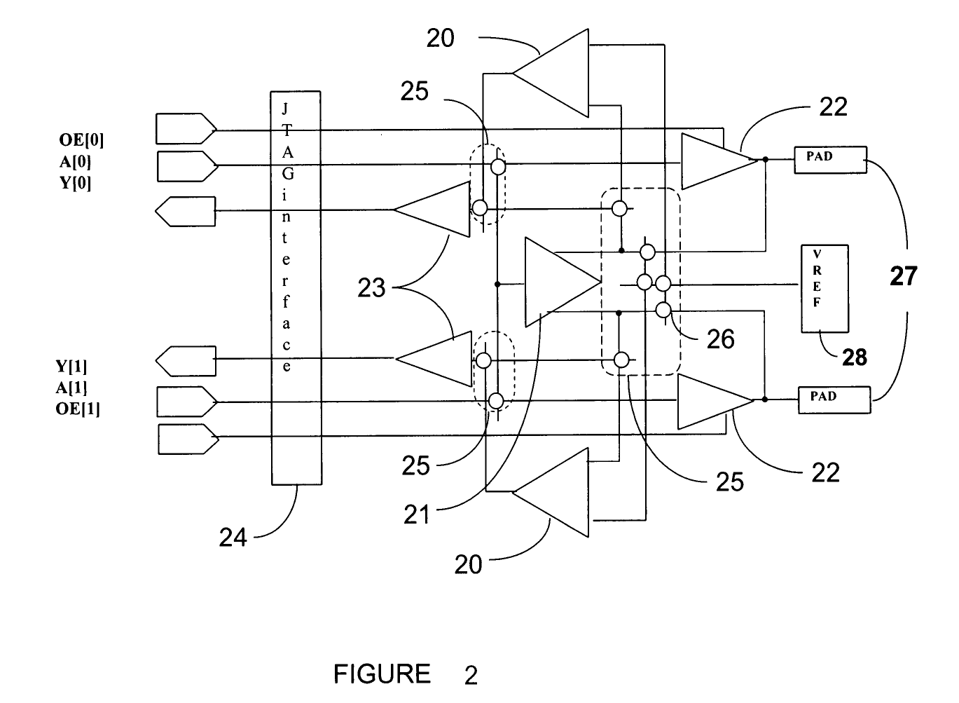

Reference is now made to FIG. 2, an illustration of a customizable I/O buffer. Each I/O buffer has two pads 27, each of which may be customized to be used as an input or output pad, and one pad 28, which may be customized to be used as a voltage reference pad. While this example has two pads 27, a customizable I/O buffer with a single pad, which may be customized to be used as an input or output pad, may be constructed.

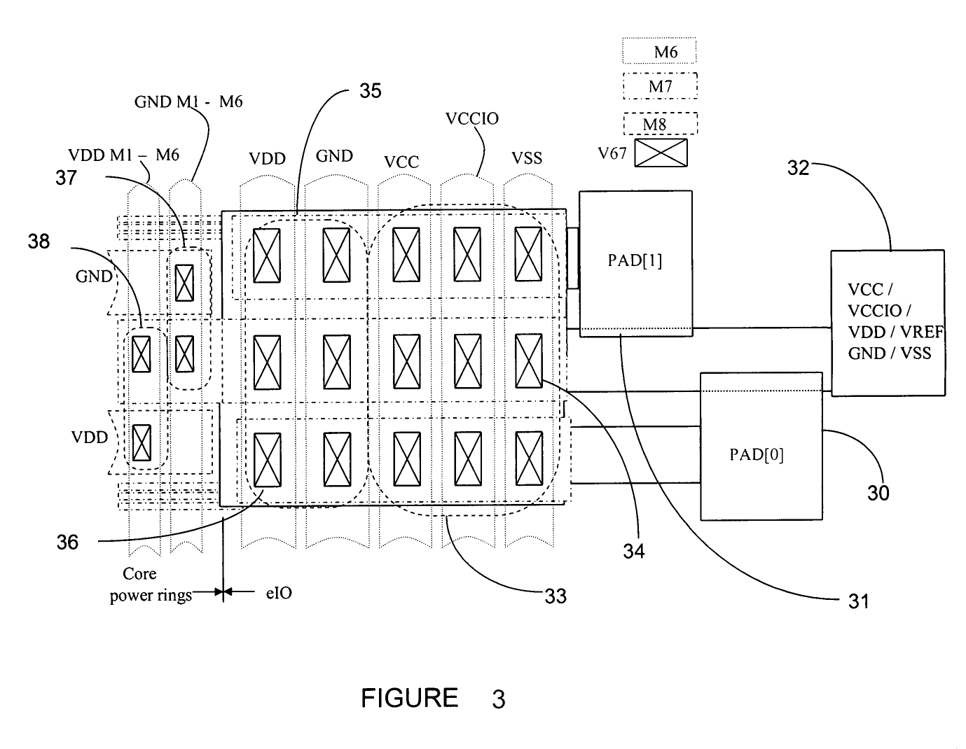

Reference is now made to FIG. 3, an illustration of the physical power and ground connections within a customizable I/O cell. When unused, each of the pads 30, 31 and 37 may be connected directly to either the internal power and ground 35 by customizing one or more of the appropriate vias 36, or to the I/O power and/or ground 33 by customizing one of more of the appropriate vias 34. Alternatively, a customizable I/O cell with only two pads or one pad, each of which may be connected to either power or ground by customizing one or more vias, may be constructed.

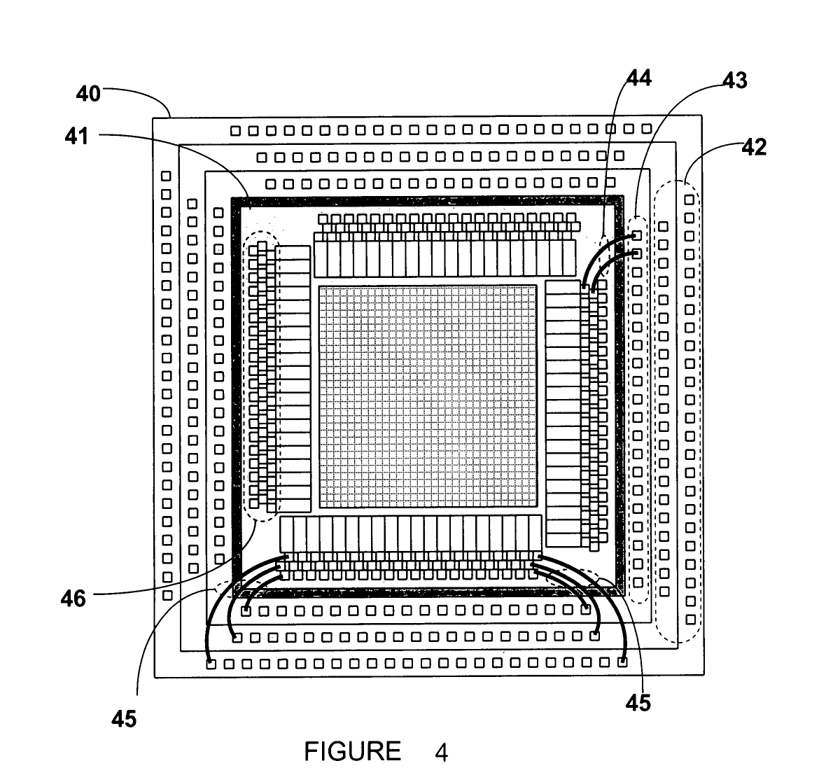

Reference is now made to FIG. 4, an illustration of a semiconductor device 41 with I/O cells in a multi-tiered package 40. The I/O buffer's three pads 46 are usually each connected to one of the tier of pads 42 and 43. The top two tiers 42 are connected, with bonding wire, to the I/O signal pads, and the voltage reference pad is usually connected to I/O power or I/O ground 45. Alternatively, an unused I/O buffer may be customized to either a power or ground pin, and then custom bonded to the I/O power or ground 44.

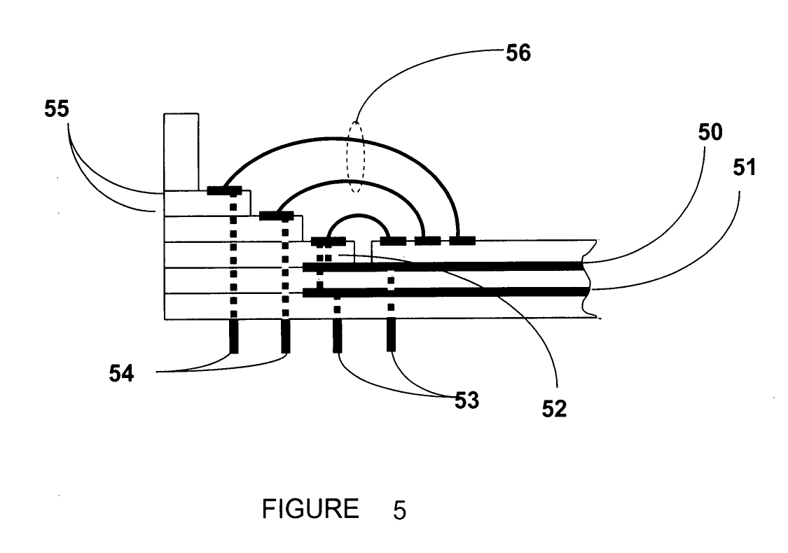

Reference is now made to FIG. 5, a side view of half of the illustration in FIG. 4. The inner tier of package pads are connected 52 to power and ground planes 50 and 51 imbedded in the package, which in turn are connected to package pins 53. The outer (and upper) tiers of the package 55 are connected directly to package pins 54. In one embodiment of the present invention, there is a fixed bonding pattern 56, which connects signal pads directly to package pins, and any unused I/O signal pad may be customized with a single via mask to become a power or ground pin.

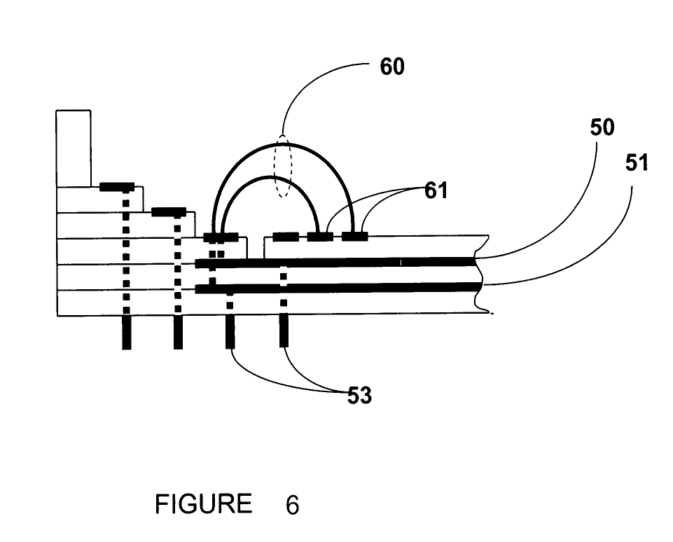

Reference is now made to FIG. 6, a side view of the package with a second bonding pattern. In another embodiment of the present invention, either signal pad 61, if unused, may be customized to a power or ground pin and, with customized bonding 60, may be connected to the internal power or ground planes of the package.

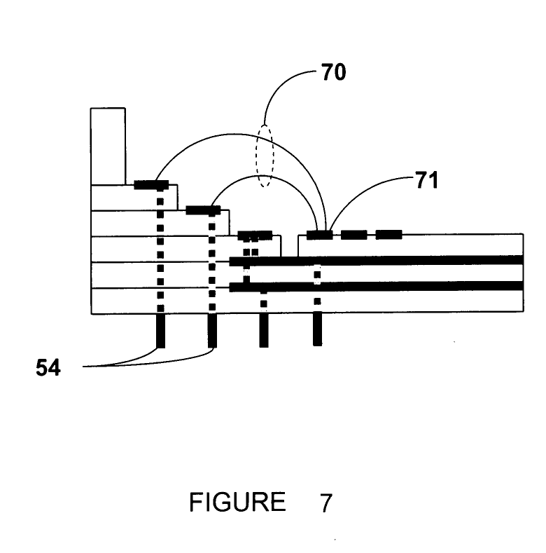

Reference is now made to FIG. 7, another side view of the package with a third bonding pattern. In yet another embodiment of the present invention, if insufficient package pads exist to connect all the third row pads to the internal power or ground planes of the package, the unused third row pads 71 may be customized to power or ground pins and connected to available package pins with a custom bonding pattern 70.

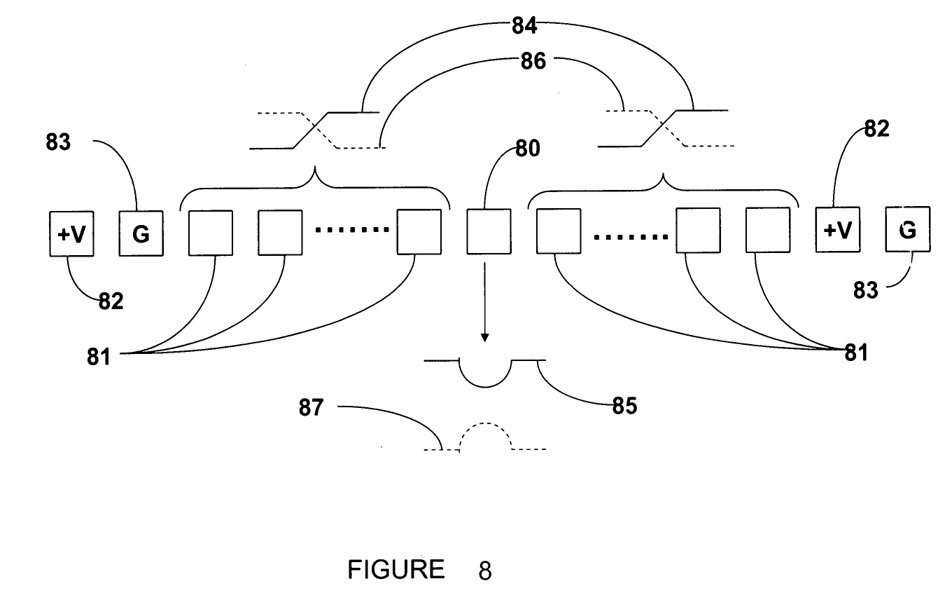

Reference is now made to FIG. 8, a diagram depicting power and ground bounce on a quiescent I/O. A central quiescent output buffer 80 is surrounded by a number of switching outputs 81, which are bounded by power 82 and ground 83 pads. If all the outputs 81 are switching high 84, and the quiescent output 80 is set at a high level, it will see a negative voltage bounce 85. On the other hand, if all the outputs 81 are switching low 86, and the quiescent output 80 is set at a low level, it will see a positive voltage bounce 87, on its output pad or pin. Any voltage bounce on an output that is sufficient to switch a receiver on another chip is unacceptably large.

There is also a potential timing problem when a large number of outputs switch in the same direction because the bounce shown on the quiescent output 80 results in slower transition times on the switching outputs, which may cause slow path timing errors in the design. Typically, the following method has been used to ensure an ASIC design has acceptable levels of simultaneous switching outputs:
a) Assign output buffers to I/O locations,
b) specify the sets of simultaneous switching outputs,
c) create a package and I/O electrical model,
d) electrically simulate simultaneous switching I/O in the package,
e) verify the results have acceptable timing and levels of signal noise (ground or voltage bounce),
f) if not, adjust I/O locations, insert power and ground pads and repeat steps b) through f).

Unfortunately, if the assignment is not initially correct, this process may iterate a number of times before acceptable timing and levels of signal noise are reached.

In yet another embodiment of the present invention, by creating an electrical model of the packaged I/O for each output buffer type and running the appropriate simultaneous switching experiments on the output buffers, a pre-calculated set of noise and delay coefficients may be generated and later used to generate a pin placement that meets noise and timing constraints.

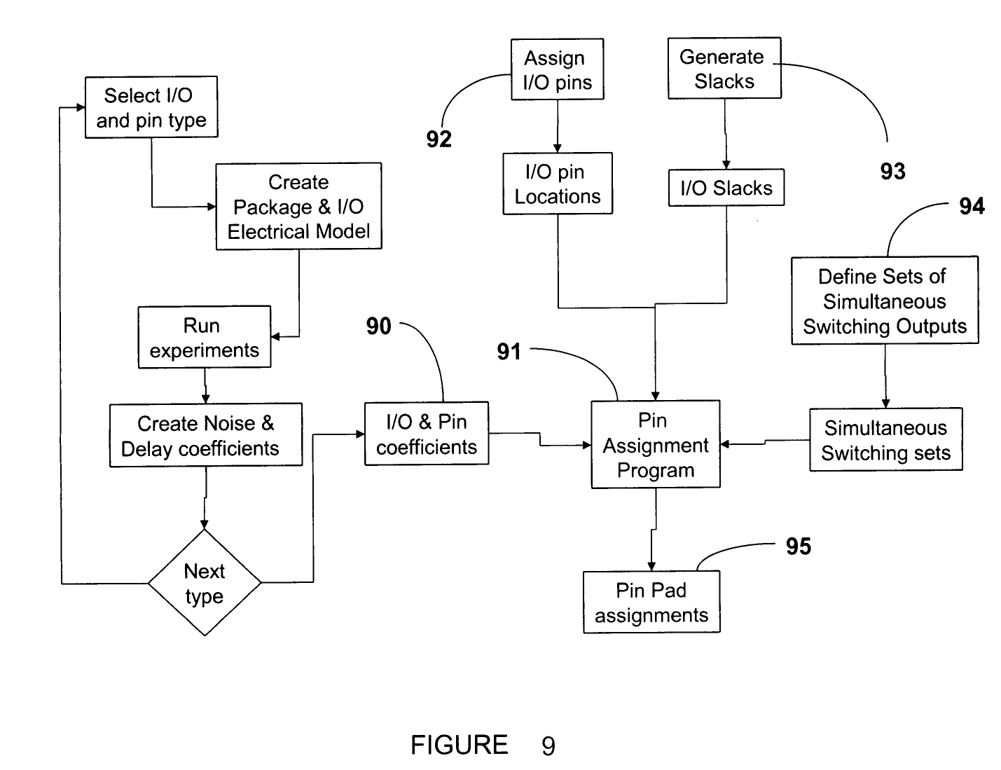

Reference is now made to FIG. 9, a flowchart depicting a process of generating the noise and delay coefficients 90 and their use in assigning pins 95, according to embodiments of the invention.

The pin assignment program 91 assigns power and ground noise coefficients to each output buffer pad in each group based on the type of output, and assigns single coefficients, based on the type of power and ground pin, to the power and ground pads. It also assigns delay coefficients to each output buffer based on the type of output. For each simultaneous switching group, it sums up the power coefficients for the buffers between each pair of power pins and multiplies the result by the coefficients for the power pins. It does the same process for the ground coefficients, and then assigns the results to all the output pads between the pairs of power and pairs of ground pads. These are each output pad's power and ground noise values. Two delay values are then generated by multiplying each transition delay coefficient by the appropriate output pad's power or ground noise value. Each output's resulting noise values are compared with the output's noise limits, and the output's delay values are compared with the output's slack (the amount of timing margin for signals on each output). If a ground noise or delay error exists within a group of simultaneous switching outputs between a pair of ground pins, because one or more of the outputs exceeds its slack or ground noise limit, an unused pad between the ground pins is converted into an additional ground pad. Similarly, if a power noise or delay error exists within a group of simultaneous switching outputs between a pair of power pins, an unused pad between the power pins is converted into an additional power pad. The type of power or ground pin bonded to the added power or ground pad is chosen to eliminate or minimize the noise and delay errors. If no unused pad exists, the output locations are shifted as little as possible to make an intermediate pad available. This process iterates until either all pads are used or all errors have been removed. The method for assigning pins is then:
a) generate the slacks for the outputs 93,
b) define pin assignments 92,
c) define sets of simultaneous switching outputs 94,
d) run the package pin assignment program 92, and
e) use the resulting pin assignment 95.

This method is preferable because, within the predefined limits of package pin assignment, the program can automatically insert the necessary power and ground pins without having to iterate through cumbersome reassignments and verifications.

It will be appreciated by persons skilled in the art that the present invention is not limited by what has been particularly shown and described hereinabove. Rather the scope of the present invention includes both combinations and sub-combinations of various features described hereinabove as well as modifications and variations which would occur to persons skilled in the art upon reading the foregoing description and which are not in the prior art.

We claim:

1. A semiconductor device comprising:
a multiplicity of customizable I/O cells, each having at least one pad,
wherein at least one of said multiplicity of customizable I/O cells has at least one said pad customized to be connected to power for said multiplicity of customizable I/O cells.

2. A semiconductor device as in claim 1, wherein said at least one said pad is customized to be connected to power by at least one via on a single via layer.

3. A package comprising:
a first multiplicity of package pads connecting to an internal power plane;
a second multiplicity of package pads, wherein each of said second multiplicity of package pads connects to a pin of said package; and,
a semiconductor device as in claim 1;
wherein at least one said pad of said I/O cell customized to be connected to power is selectively connected to one of the group consisting of: said first multiplicity of package pads and said second multiplicity of package pads.

4. A semiconductor device comprising:
a multiplicity of customizable I/O cells, each having at least one pad,
wherein at least one of said multiplicity of customizable I/O cells has at least one said pad customized to be connected to ground for said multiplicity of customizable I/O cells.

5. A semiconductor device as in claim 4, wherein said at least one said pad is customized to be connected to ground by at least one via on a single via layer.

6. A package comprising:
a first multiplicity of package pads connecting to an internal ground plane;
a second multiplicity of package pads, wherein each of said second multiplicity of package pads connects to a pin of said package; and,
a semiconductor device as in claim 4;
wherein at least one said pad of said I/O cell customized to be connected to ground is selectively connected to one of the group consisting of: said first multiplicity of package pads and said second multiplicity of package pads.

7. A semiconductor device as in claim 4, wherein at least one of said customizable I/O cells further has at least one pad customized to be connected to power.

8. A method for defining the placement of power and ground connections for a semiconductor device within a package, said semiconductor device comprised of a multiplicity of I/O cells, selectively customizable into one of a multiplicity of output types, the method including the steps of:
a) creating an electrical model of each output type,
b) running simultaneous switching experiments on said models,
c) generating a set of noise and delay coefficients for said each output type, and
d) using said coefficients to modify the placement of said I/O cells to meet noise and timing constraints.

9. A method as in claim 8, wherein said using said coefficients to modify the placement of said I/O cells includes inserting at least one I/O cell customized as a power connection.

10. A method as in claim 8, wherein said using said coefficients to modify the placement of said I/O cells includes inserting at least one I/O cell customized as a ground connection.
